(19) United States
(12) Patent Application Publication
(10) Pub. No.: US 2018/0087959 A1
(43) Pub. Date: Mar. 29, 2018

(54) LASER POWER AND ENERGY SENSOR USING ANISOTROPIC THERMOELECTRIC MATERIAL

(71) Applicant: Coherent, Inc., Santa Clara, CA (US)

(72) Inventors: Erik KROUS, Tualatin, OR (US); Jimson LOUNSBURY, Woodburn, OR (US); Joseph IMAMURA, Lake Oswego, OR (US); James SCHLOSS, Tigard, OR (US)

(21) Appl. No.: 15/712,513

(22) Filed: Sep. 22, 2017

Related U.S. Application Data
(60) Provisional application No. 62/401,437, filed on Sep. 29, 2016.

(51) Int. Cl. G01J 1/04; G01J 1/42; G01J 5/04; H01L 31/0368; G01K 17/00

(52) U.S. Cl. CPC G01J 1/0407; G01J 1/42; G01K 17/003; H01L 31/0368; G01J 5/046

(57) ABSTRACT

A laser-radiation detector is formed from a plurality of layers supported on a substrate. The plurality of layers includes a reflective metal layer and an oriented polycrystalline sensor-layer positioned between the metal layer and the substrate.

### PRIORITY CLAIM

This application claims priority of U.S. Provisional Application No. 62/401,437, filed Sep. 29, 2016, assigned to the assignee of the present invention, and the complete disclosure of which is hereby incorporated herein by reference.

### TECHNICAL FIELD OF THE INVENTION

The present invention relates in general to laser-radiation detectors. The invention relates in particular to laser-radiation detectors having a fast response time and capable of measuring high laser-radiation power, for example, in excess of about 10 Watts (W).

### DISCUSSION OF BACKGROUND ART

One relatively new type of laser-radiation (optical radiation) detector, which offers a temporal response comparable to a photodiode detector and a spectral response comparable with a thermopile detector, is based on using a layer of an anisotropic transverse thermoelectric material as a detector element. Such an anisotropic layer is formed by growing the material in an oriented polycrystalline crystalline form, with crystals inclined non-orthogonally to the plane of the layer.

The anisotropic layer absorbs radiation to be measured, thereby heating the layer. This heating creates a thermal gradient through the anisotropic material in a direction perpendicular to the layer. This thermal gradient, in turn, creates an electric field orthogonal to the thermal gradient. The electric field is proportional to the intensity of incident radiation absorbed. Such a detector may be referred to as a transverse thermoelectric effect detector. If the anisotropic layer is made sufficiently thin, for example only a few micrometers thick, the response time of the detector will be comparable with that of a photodiode detector. Spectral response is limited only by the absorbance of the anisotropic material.

Oriented polycrystalline layers can be deposited by a well-known inclined substrate deposition (ISD) process. This process is described in detail in U.S. Pat. No. 6,265,353 and in U.S. Pat. No. 6,638,598. Oriented polycrystalline layers have also been grown by a (somewhat less versatile) ion-beam assisted deposition (IBAD) process. One description of this process is provided in a paper “Deposition of in-plane textured MgO on amorphous Si₃N₄ substrates by ion-beam-assisted deposition and comparisons with ion-beam-assisted deposited yttria-stabilized-zirconia” by C. P. Wang et. al, Applied Physics Letters, Vol 71, 20, pp 2955, 1997.

A detailed description of laser-radiation detectors, including an anisotropic transverse thermoelectric material as a detector element, is provided in U.S. Pat. No. 9,012,848 and in U.S. Pat. No. 9,059,346, the entire disclosures of which are incorporated herein by reference. The radiation detectors described therein are configured for measuring relatively low radiation levels. In each case, the radiation detectors include a copper substrate on which is grown a tilted polycrystalline buffer layer. A tilted polycrystalline transverse thermoelectric (detector) layer is grown on the buffer layer. One or more barrier layers are grown on the detector layer to provide a barrier for protecting the detector layer from atmospheric degradation. A layer of highly absorbing material is deposited on the barrier.

A particular problem with transverse thermoelectric effect detectors is a limited capability for heat-sinking the substrate on which the layers are deposited. This limits the power-handling capability of the radiation detector, and may lead to a non-linear response. Attempting to directly measure output power of high-power industrial lasers (such as high-power continuous-wave fiber lasers or carbon dioxide lasers) having an output powers of 1 kilowatt (kW) or more could result in rapid destruction of the radiation detector.

There is a need for transverse thermoelectric effect detector which can survive exposure to laser-powers of about 1 kW or greater. Preferably, the detector should retain the measurement accuracy and rapid response time of prior-art anisotropic thermoelectric detectors.

### SUMMARY OF THE INVENTION

In one aspect of the present invention, a laser-radiation detector comprises a substrate and a plurality of layers supported on the substrate. The plurality of layers includes a reflective coating and an oriented polycrystalline sensor-element layer positioned between the reflective coating and the substrate.

In another aspect of the present invention, apparatus for measuring power of a laser-radiation beam, comprises a housing and a laser-radiation detector located in the housing. The laser-radiation detector includes a plurality of layers supported on a substrate. The plurality of layers includes a reflective coating, and an oriented polycrystalline sensor-element layer positioned between the reflective coating and the substrate. The housing is configured to provide optical access for the laser-radiation beam to be incident on the detector. The detector and the housing are cooperatively arranged such that the laser-radiation beam is non-normally incident on the detector, and such that radiation from the incident laser beam is reflected by the reflective coating and trapped within the housing.

### BRIEF DESCRIPTION OF THE DRAWINGS

FIG. 1 schematically illustrates a preferred embodiment of a transverse thermoelectric effect detector in accordance with the present invention, including a substrate surmounted by a tilted polycrystalline buffer layer, a tilted polycrystalline transverse thermoelectric effect layer grown on the polycrystalline buffer layer, a passivation and isolation barrier surmounting the transverse thermoelectric effect layer, and a reflective layer surmounting the passivation and isolation barrier.

FIG. 2 is a side-elevation view, partially in cross-section, schematically illustrating a preferred embodiment of transverse thermoelectric effect detector apparatus in accordance with the present invention, including the transverse thermoelectric effect detector of FIG. 1, located in a housing and optically accessible via an aperture in the housing, the housing including a heat-sink, and the detector and housing arranged such that radiation entering the housing is reflected from the detector and absorbed by the heat sink.

FIG. 3 is a graph schematically illustrating measured step response of an exemplary detector as a function of time exposed to the radiation entering the housing in an example of the apparatus of FIG. 2.

### DETAILED DESCRIPTION OF THE INVENTION

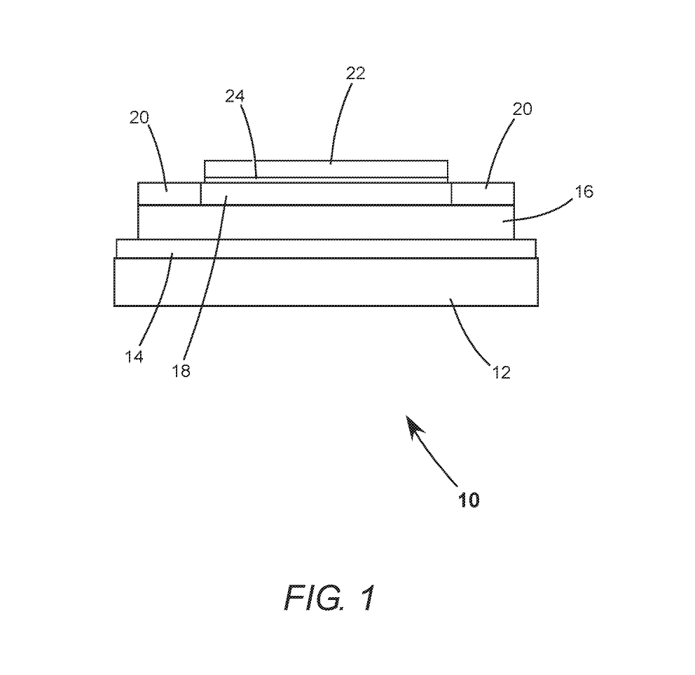

Turing now to the drawings, wherein like features are designated by like reference numerals, FIG. 1 schematically illustrates a preferred embodiment 10 of a transverse thermoelectric effect detector in accordance with the present invention. Detector 10 includes a substrate 12 surmounted by a tilted polycrystalline buffer layer 14. A tilted polycrystalline transverse thermoelectric effect layer 16 is grown on the polycrystalline buffer layer. A passivation and isolation barrier 18 surmounts the transverse thermoelectric effect layer. Barrier 18 may be provided by a single layer or by two or more layers as described in the above reference patents. A reflective coating 22 surmounts barrier 18. The reflective coating is preferably formed by a metal layer, in which case an intermediate layer 24 of a metal such as chromium (Cr) may be provided between reflective coating 22 and barrier 18 to promote adhesion of the reflective coating to the barrier. Contacts 20 are provided for making electrical connections to transverse thermoelectric effect layer 16.

In a preferred embodiment, the substrate is formed from copper. Additional layers (not shown) can be added to provide electrical isolation and to fill voids in lower layers.

Preferred metals for reflective coating 22 are gold (Au), silver (Ag), and Aluminum (Al). All three metals exhibit greater than about 90% reflectivity at wavelengths longer than 1 micrometer (μm) for metal layers thick enough to be opaque. Silver and aluminum are preferred to gold at shorter wavelengths, such as visible and near infrared (NIR) wavelengths. Reflectivity at visible and NIR wavelengths may be enhanced by depositing two or more dielectric layers on the metal layer, as is known in the optical-coating art. This also provides that the reflector can be “tailored”, if desired, for a particular wavelength or wavelength-range. The reflective layer may be partially transmissive, depending on anticipated power ranges to be measured. The reflective coating should have a reflectivity of at least 70% at the wavelength of interest, and more preferably at least 80% and most preferably at least 90%.

In effect, the inventive detector is a detector designed and built as described in the above referenced '848 and '346 patents, but with the highly absorbing layer eliminated, and replaced by reflective layer. Absorption is not completely eliminated, as when the metal layer is thick enough to be fully reflective (not transmitting). What is not reflected will be absorbed, as all metal layers are partially absorbing to a significant extent, as is known in the art. The absorption level, however, will typically be more than an order-of-magnitude less than in the prior-art detectors, having a highly absorbing coating thereon. This allows the inventive detector to directly measure high-power radiation, for example in excess of 1 kW, without encountering heat-sinking problems of the prior-art detectors. The term “directly measure”, here, means measuring a raw beam rather than a sample of a beam.

Those skilled in the optical-coating art will recognize, in theory at least, that a multilayer dielectric stack may be substituted for a metal layer in reflective coating 22, depending on power to be measured, and on materials of the detector. As multilayer dielectric stacks are not significantly absorbing, substituting dielectric stacks as a reflector would only be practical in cases where the detector would tolerate transmitted radiation.

One thing that must be considered in using the inventive detector, especially for measuring a beam of laser-radiation, is that most of the measured power will be reflected from the detector. As this may be 1 kW or greater, it is highly desirable that the reflected power not be fed back into the laser delivering the power or to vulnerable objects in the vicinity of the detector. Also, it is highly desirable that the reflected power not be directed onto the transverse thermoelectric effect layer, which would make the instrument sensitive to the parameters of the laser-radiation beam, such as beam diameter, beam divergence, and angle-of-incidence to detector 10.

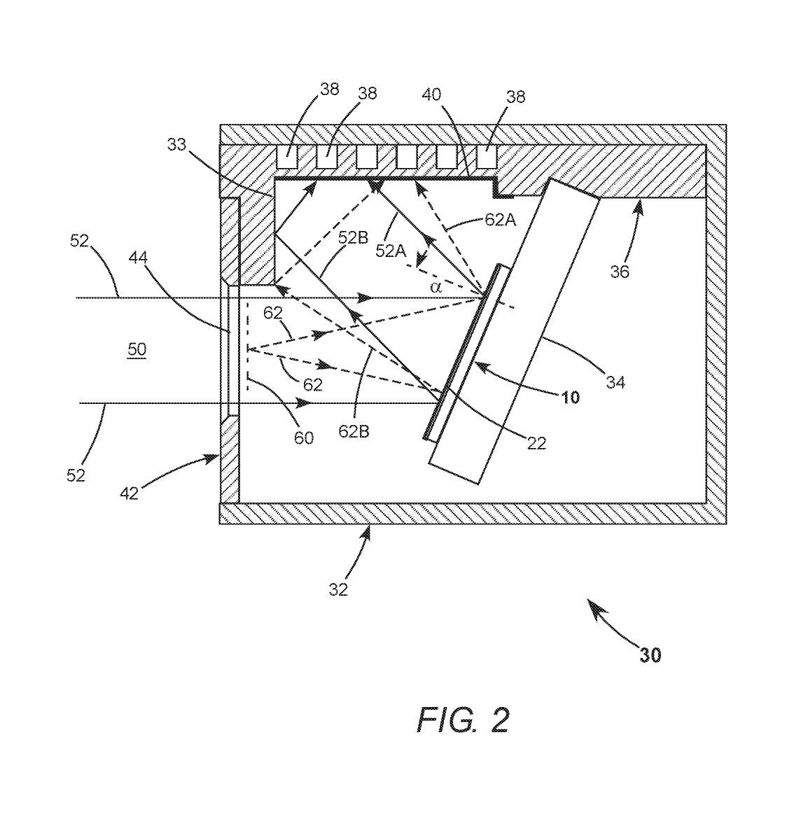

FIG. 2, schematically illustrates a preferred embodiment 30 of power measurement apparatus in accordance with the present invention. The apparatus incorporates the above-described inventive detector and is designed and constructed in a way that traps all radiation reflected from the detector, such that the radiation neither escapes into surroundings nor is reflected back to the laser, nor is it reflected and scattered back to transverse thermoelectric effect layer 16.

Power measurement apparatus 30 includes a housing 32. Within housing 32 is a cooling plate 34 on which inventive detector 10 is mounted. Cooling plate 34 is preferably water-cooled. Water cooling connections to cooling plate 34 and electrical connections to detector 10 are not shown in the drawing for simplicity of illustration. Also within housing 32 is a cooling plate 36, a portion of which includes a plurality of cooling channels 38 therein through which a cooling fluid can be flowed. On the portion of cooling plate 36 including cooling channels 38 is a layer 40 of a material highly absorbing for wavelengths of radiation to be measured. Radiation absorbing layer 40 preferably has a matt finish and absorbs 90% or more of radiation incident thereon, with radiation not absorbed scattered over a large solid-angle. Radiation absorbing layer 40 may be made from any refractory black paint on a rough surface, or be layer of a flame spayed ceramic.

Housing 32 includes an aperture-plate 42 having an aperture 44 therein providing optical access to detector 10 for radiation being measured. Radiation may be delivered in the form of a collimated beam 50 bounded by rays 52 designated by solid lines. Such a beam may, for example, have a diameter between about 10 mm and about 30 mm. Alternatively, aperture-plate 42 can be configured to accept a fiber optic connector (not shown) allowing radiation to be delivered via an optical fiber. An exit-plane 60 of such a fiber is designated by a dotted and dashed line. This can also be considered as an aperture providing optical access to detector 10. Radiation exits the fiber in a diverging beam as indicated by boundary rays 62 designated by dashed lines. The beam-divergence depends on the numerical aperture (NA) of the fiber, as is known in the art.

Detector 10 is inclined at an angle α to the collimated or diverging input beams such that no radiation incident on the detector is reflected directly back through aperture 44 or fiber exit-plane 60. Radiation is either reflected directly to radiation absorbing layer 40 (see rays 52A and 62A), or to a wall 33 of cooling plate 36. Wall 33 preferably has a reflective coating (not shown) thereon such that rays such as ray 52B and 62B are “steered” to radiation absorbing layer 40. As noted above, there may some radiation scattered from radiation absorbing layer 40. This could find a path to aperture 44 following subsequent reflections or scatterings from walls of the housing, or from objects within the housing, but any such radiation would have negligible power compared with that of the input radiation or directly reflected radiation. Accordingly, for all practical purposes, radiation reflected from reflective coating 22 of detector 10 can be considered as being trapped in housing 32.

It is emphasized here that the arrangement of housing 32 is but one example of an arrangement for trapping radiation reflected from the inventive detector. Those skilled in the art, from the description of the present invention presented herein, may devise other arrangements without departing from the spirit and scope of the present invention. The angle-of-incidence a of radiation incident on the detector is not critical and can be selected according to the beam-diameter, the numerical aperture of fiber-delivered radiation, and the particular configuration of the housing and heat-sinking arrangements to provide optimum radiation-trapping.

Prototype sensor apparatus similar to that described above has been tested with radiation to be measured delivered in a collimated beam in free space (collimated beam 50) and by an optical fiber. In each case, the power in the beam was 1.1 kW. The apparatus was run for multiple tens-of-minutes continuously in both the free space and fiber delivered configurations. The beam diameter on the detector was about 10 mm. The reflective coating 22 of the detector was a gold layer, having a thickness of about 150 nanometers (nm). An adhesion layer of chromium, having a thickness of about 5 nm, was provided. The transverse thermoelectric effect layer was a layer of dysprosium barium copper oxide, symbolically referred to by practitioners of the art as DyBCO.

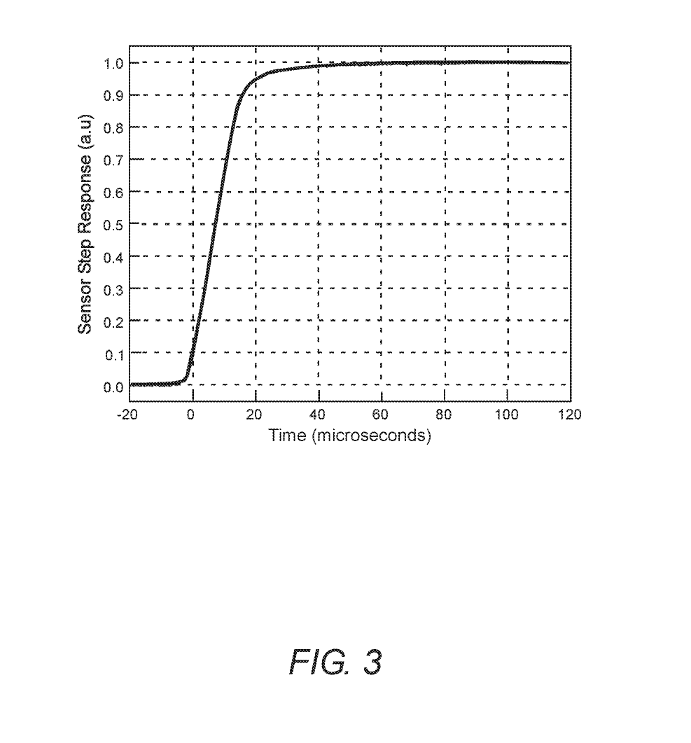

FIG. 3 is schematically illustrates normalized, measured step-response as a function of time of the exemplary detector discussed above exposed to a continuous-wave beam having a power of 1.1 kW. Initial exposure of the detector to the beam being measured occurred at about minus 4 microseconds (μs) on the time scale. Measured power was 98% of peak after 40 μs. Prior-art power sensors having just an absorbing thermopile material would be permanently damaged by such exposure.

In summary, the present invention is described above with reference to preferred embodiments. The invention is not limited, however, to the embodiments described and depicted herein. Rather the invention is limited only by the claims appended hereto.

What is claimed is:

1. A laser-radiation detector, comprising:
a substrate; and
a plurality of layers supported on the substrate, the plurality of layers including a reflective coating and an oriented polycrystalline sensor-element layer positioned between the reflective coating and the substrate and wherein the reflective coating has a reflectivity for the wavelength of the laser radiation of at least 70 percent.

2. The laser-radiation detector of claim 1, wherein the reflective coating includes a metal layer.

3. The laser-radiation detector of claim 2, wherein the metal layer is one of a silver layer and a gold layer.

4. The laser-radiation detector of claim 1, wherein the reflective coating is partially absorbing.

5. The laser-radiation detector of claim 1, wherein the oriented polycrystalline sensor-element layer is a layer of dysprosium barium copper oxide.

6. The laser-radiation detector of claim 1, wherein the reflective coating has a reflectivity for the wavelength of the laser radiation of at least 90 percent.

7. The laser-radiation detector of claim 1, wherein laser-radiation reflected by the reflective coating is trapped within a housing surrounding the detector.

8. The laser-radiation detector of claim 7, wherein the trapped laser-radiation is absorbed by an internal radiation-absorbing layer formed on an inner wall of the housing, said radiation-absorbing layer being highly absorbing for the wavelength of the laser radiation.

9. Apparatus for measuring power of a laser-radiation beam, comprising:
a housing;
a laser-radiation detector located in the housing, the laser-radiation detector including a plurality of layers supported on a substrate, the plurality of layers including a reflective coating, and an oriented polycrystalline sensor-element layer positioned between the reflective coating and the substrate, and
wherein the housing is configured to provide optical access for the laser-radiation beam to be incident on the detector, with the detector and the housing being cooperatively arranged such that the laser-radiation beam is non-normally incident on the detector, and such that radiation from the incident laser beam is reflected by the reflective coating and trapped within the housing.

10. The apparatus of claim 9, wherein the reflective coating includes a metal layer.

11. The apparatus of claim 10, wherein the metal layer is one of a silver layer and a gold layer.

12. The apparatus of claim 9, wherein the reflective coating is partially absorbing.

13. The apparatus of claim 9, wherein the oriented polycrystalline sensor-element layer is a layer of dysprosium barium copper oxide.

14. The apparatus of claim 9, wherein the housing includes an internal radiation-absorbing layer arranged to absorb radiation reflected from the reflective coating.

15. The apparatus of claim 14, wherein the housing includes a fluid-cooled heat sink and the radiation-absorbing layer surmounts on the heat sink.

16. The apparatus of claim 9, wherein the optical access for the laser-radiation beam is provided by an aperture in the housing.

17. The apparatus of claim 16, wherein the laser-radiation beam is a collimated laser-radiation beam propagated through the aperture to the detector.

18. The apparatus of claim 9 wherein the reflective coating has a reflectivity for the wavelength of the laser radiation beam of at least 70 percent.

19. The apparatus of claim 9 wherein the reflective coating has a reflectivity for the wavelength of the laser radiation beam of at least 90 percent.
